(19) United States
(12) Patent Application Publication
(10) Pub. No.: US 2003/0205822 A1
(43) Pub. Date: Nov. 6, 2003

(54) Low-strength plasma treatment for interconnects

(75) Inventors: Keng-Chu Lin, Ping-Tung (TW); Shwang-Ming Jeng, Hsin-chu (TW); Shing-Chyang Pan, Tainan (TW)

Correspondence Address: TUNG & ASSOCIATES, Suite 120, 838 W. Long Lake Road, Bloomfield Hills, MI, 48302, US

(73) Assignee: Taiwan Semiconductor Manufacturing Co. Ltd.

(21) Appl. No.: 10/137,693

(22) Filed: May 2, 2002

(51) Int. Cl. H01L 23/053; H01L 23/12; H01L 23/48; H01L 23/52; H01L 29/40

(52) U.S. Cl. 257/774; 257/700; 257/701; 257/758

(57) ABSTRACT

Low-strength plasma treatment for interconnects is disclosed. A low k dielectric-metal interconnect is formed that has a top surface, via a damascene process, such as a single- or a dual-damascene process. The top surface of the low k dielectric-metal interconnect is low-power plasma treated to substantially cure any damage to the top surface resulting from the damascene process. Such damage may include the entrapment of metal ions, such as copper ions where the metal of the interconnect is copper, and chemical-mechanical planarization (CMP) materials resulting from the CMP employed during the damascene process, within the top surface of the low k dielectric-metal interconnect. The low-power plasma used may be helium plasma.

### FIELD OF THE INVENTION

This invention relates generally to semiconductor devices, and more particular to the interconnects of such devices, such as damascene and dual-damascene interconnects.

### BACKGROUND OF THE INVENTION

Via holes are semiconductor device features that are through holes made in a substrate, for a variety of different purposes. Via holes may be used to ground semiconductor devices and passive devices. Via holes may be made through dielectric layers, for subsequent metal deposition to form a plug and create an interconnect between two metal lines. Multi-level interconnect schemes may employ such via holes. Processes used to perform such interconnection using via holes include the damascene process and the dual-damascene process.

In the single-damascene process, interconnect metal lines are delineated in dielectrics, isolating them from each other using chemical-mechanical planarization (CMP). The interconnect pattern is first lithographically defined in the dielectric layer, and then metal is deposited to fill the resulting trenches. Excess metal is removed by CMP. The dual-damascene process is a modified version of the single-damascene process, and is also used to form metal interconnect geometries using CMP. In the dual-damascene process, two inter-layer dielectric patterning steps and one CMP step creates the pattern that would require two patterning steps and two metal CMP steps if the conventional damascene process were instead used. Whereas a trench is formed in the damascene process, a trench and a via hole are formed in the dual-damascene process.

The fundamental difference of damascene processing relative to standard processing is that metal lines are not etched, but deposited in grooves within the dielectric layer, and excess metal is removed by CMP. Both damascene processes are considered the future technology of choice for laying metal lines and interconnects on semiconductor devices. The damascene process is commonplace for 0.18-0.13 micron technology, whereas the dual-damascene process is more common for 0.13-0.10 micron technology.

FIGS. 1A-1D show a typical process for forming damascene and dual-damascene interconnect structures. In FIG. 1A, the device 100 includes a stop layer 104 that has been deposited, over which a low-k dielectric layer 106 has been deposited, and over which an anti-reflective coating (ARC) layer 108 has been deposited. The stop layer 104 is specifically deposited on a substrate of a semiconductor wafer not shown in FIG. 1A. The low-k dielectric layer 106 is a dielectric that has a low dielectric constant. The layer 106 may also be an inter-layer dielectric (ILD). The stop layer 104 is typically 500-800 angstroms in height, whereas the layer 106 is typically 7,000-8,000 angstroms in height, and the layer 108 is typically 1,000 angstroms in height.

In FIG. 1B, a via hole 110 and a trench 112 have been etched through the layers 104, 106, and 108, making the device 100 ready for metal deposition. The via hole 110 and the trench 112 constitute the damascene profile of the device 100, which may be a single-damascene profile or a dual-damascene profile. In FIG. 1C, a metal layer 114 has been deposited. The metal layer 114 may be copper or another metal. Typically, the metal layer 114 has a height of about 6,000 angstroms over the ARC layer 108. The metal layer 114 is then planarized using CMP, past the ARC layer 108 and into the layer 106. This is shown in FIG. 1D. Also shown in FIG. 1D is that another stop layer 116 has been deposited, for a further interconnect layer to be added. Thus, CMP is used to remove unnecessary metal, and form a damascene interconnect structure. The resulting device 100 in FIG. 1D thus is or otherwise includes a low k dielectric-metal interconnect structure due to the metal layer 114 and the low k dielectric layer 106.

A problem with the process outlined in FIGS. 1A-1D is that the performance of CMP can damage the low-k dielectric layer 106. This is shown in FIG. 2. FIG. 2 shows the device 100 after it has been planarized, and thus is consistent with FIG. 1D, except that the additional stop layer 116 of FIG. 1D has yet to be deposited. However, the low-k dielectric layer 106 has been damaged at its top surface 202 by using CMP. In particular, metal ions from the metal layer 114 and undesired materials from the CMP are trapped in the top surface 202. The metal ions may be copper ions. The combination of the undesired CMP materials and the metal ions means that a conductive path 204 between the via hole 110 and the trench 112, generically called lines, exists. This conductive path 204 is problematic, because it allows inter-line leakage current from the via hole 110 to the trench 112. Furthermore, water may absorb in the low-k dielectric layer 106, further increasing the line-to-line current leakage current.

Therefore, there is a need to overcome these disadvantages associated with the prior art. In particular, there is a need to reduce inter-line leakage current of metal (such as copper) and low-k dielectric interconnects. Such reduction should still allow the use of CMP in the damascene and dual-damascene processes, however. For these and other reasons, there is a need for the present invention.

### SUMMARY OF THE INVENTION

The invention relates to a low-strength plasma treatment for interconnects. A first method of the invention includes forming a low k dielectric-metal interconnect having a top surface, via a damascene process. The method low-power plasma treats the top surface of the low k dielectric-metal interconnect to substantially cure any damage to the top surface resulting from the damascene process. The low-power plasma used may be helium plasma.

A second method of the invention first deposits a stop layer, a low k dielectric layer, and an anti-reflective coating (ARC) layer on a substrate. The method etches through at least two of the stop layer, the low k dielectric layer, and the ARC layer in accordance with a desired damascene profile. A metal layer is deposited over the stop layer and within the layers that have been etched. Chemical-mechanical planarization (CMP) is employed to planarize the metal layer through the stop layer and a portion of the low k dielectric layer. The method finally low-power plasma treats the top surface of the low k dielectric layer as planarized to substantially cure any damage to the top surface resulting from the CMP.

A semiconductor device of the invention includes a low k dielectric metal interconnect. The interconnect includes a stop layer, a low k dielectric layer, and a metal layer. The stop layer and the low k dielectric layer have a damascene profile. The metal layer at least fills the damascene profile. CMP is employed to planarize the metal layer through a portion of the low k dielectric layer. The top surface of the low k dielectric layer after planarization is low-power plasma treated to substantially cure any damage to the top surface resulting from the CMP.

Embodiments of the invention provide for advantages over the prior art. The low-power plasma treatment of the low k dielectric layer after CMP is performed removes any trapped materials in the top surface of this layer, such as metal ions, undesired CMP materials, and so on. Thus, inter-line current leakage is substantially prevented, inasmuch as the current leakage path is removed. The low-power plasma treatment, which may be a helium plasma treatment, also serves to generally cure this top surface if it is damaged. Furthermore, the low-power plasma treatment may be considered a heat treatment that drives out any water within the low k dielectric layer itself.

Still other advantages, aspects, and embodiments of the invention will become apparent by reading the detailed description that follows, and by referencing the accompanying drawings.

### BRIEF DESCRIPTION OF THE DRAWINGS

FIGS. 1A-1D are diagrams illustratively showing a typical damascene process for forming a low k dielectric-metal interconnect. The damascene process may be a single- or a dual-damascene process, either of which uses chemical-mechanical planarization (CMP). The process results in a damaged top surface of the low k dielectric layer of the interconnect, which can be cured by using an embodiment of the invention.

FIG. 2 is a diagram showing in detail the damage that results to the top surface of the low k dielectric-metal interconnect formed by the process illustrated in FIGS. 1A-1D. The damage is specifically the entrapment of undesired CMP materials and metal ions in the top layer of the low k dielectric layer, allowing undesired inter-line leakage current.

FIGS. 3A and 3B are diagrams illustratively showing a low-power plasma treatment according to an embodiment of the invention to substantially cure the damage that results to the top surface of the low k dielectric-metal interconnect in using the CMP of a damascene process. The treatment specifically removes trapped CMP materials and metal ions from the top surface of the interconnect.

FIG. 4 is a flowchart according to an embodiment of the invention.

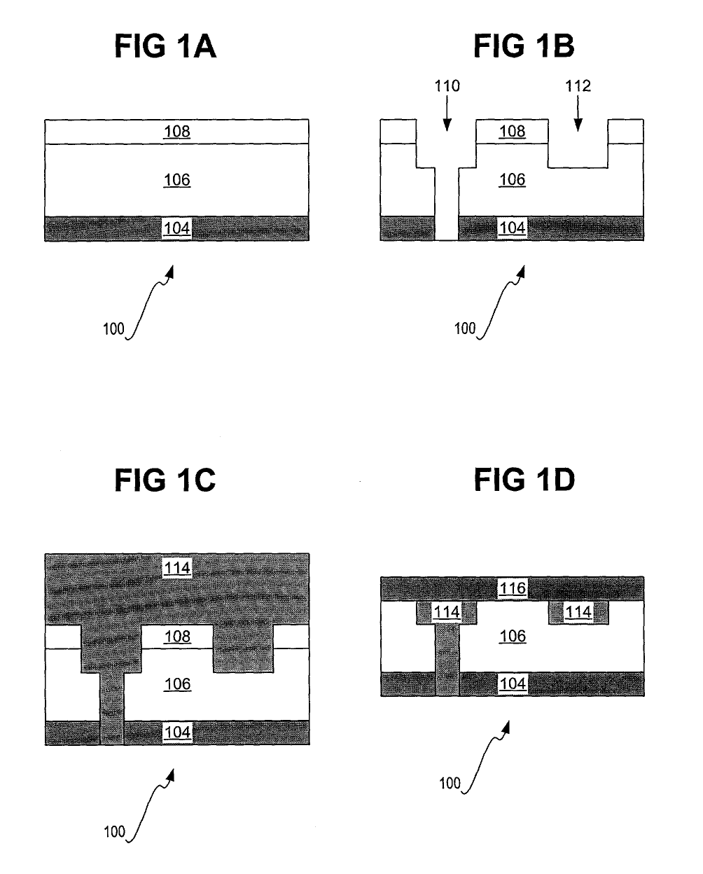

### DETAILED DESCRIPTION OF THE INVENTION

In the following detailed description of exemplary embodiments of the invention, reference is made to the accompanying drawings that form a part hereof, and in which is shown by way of illustration specific exemplary embodiments in which the invention may be practiced. These embodiments are described in sufficient detail to enable those skilled in the art to practice the invention. Other embodiments may be utilized, and logical, mechanical, and other changes may be made without departing from the spirit or scope of the present invention. The following detailed description is, therefore, not to be taken in a limiting sense, and the scope of the present invention is defined only by the appended claims.

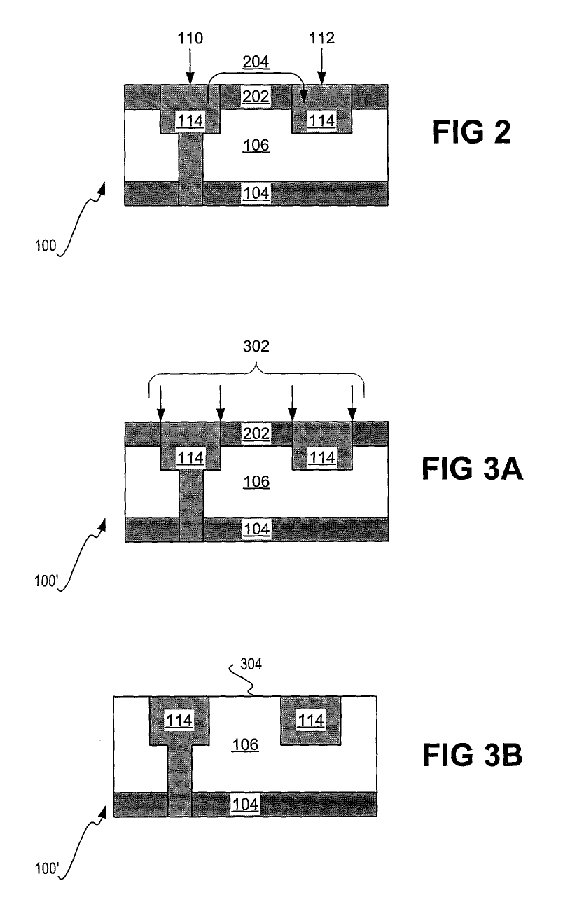

FIGS. 3A and 3B show the process followed by an embodiment of the invention to cure the damage resulting to the top surface 202 of the device 100 of FIG. 2 from the chemical-mechanical planarization (CMP) of the metal layer 114 through the low k dielectric layer 106. In FIG. 3A, the top surface 202 of the device 100, indicated as the device 100′, is low-power plasma treated, as indicated by the arrows 302. The low-power plasma treatment may be a helium plasma treatment. Preferably there is no chemical interaction with either the metal layer 114 or the top surface 202 of the low k dielectric layer 106 and the plasma, but rather only a physical bombardment by the plasma. It is been found that argon plasma is not suitable, as it is not low-power, but rather too strong, resulting in damage to the metal layer 114 where the metal is copper, as well as to the low k dielectric layer 106.

The low-power plasma treatment serves to cure the damage resulting to the top surface from the CMP of the metal layer through the low k dielectric layer 106. The term cure as used herein means to fix or repair, as opposed to other meanings of the term cure. Specifically, the low-power plasma treatment removes trapped materials within the top surface 202. These trapped materials can include the metal ions from the metal layer 114, such as copper ions, as well as undesired CMP materials. By removing these materials, the inter-line current leakage path is removed, substantially eliminating inter-line current leakage. The low-power plasma treatment also serves to otherwise cure or patch the damaged top surface 202 of the low k dielectric layer 106.

This is shown in FIG. 3B, where the damaged top surface 202 has been cured such that it is no longer present in the device 100′. Instead, the top surface 304 of the low k dielectric layer 106 is substantially the same as any other part of the low k dielectric layer 106. It is noted that the device 100′ is indicated as such to differentiate it from the device 100 as has been described in the background section, insofar as the device 100′ has had a low-power plasma treatment applied thereto. Preferably, the low-power plasma treatment is a 300-watt treatment applied at ten seconds, although the invention itself is not so limited.

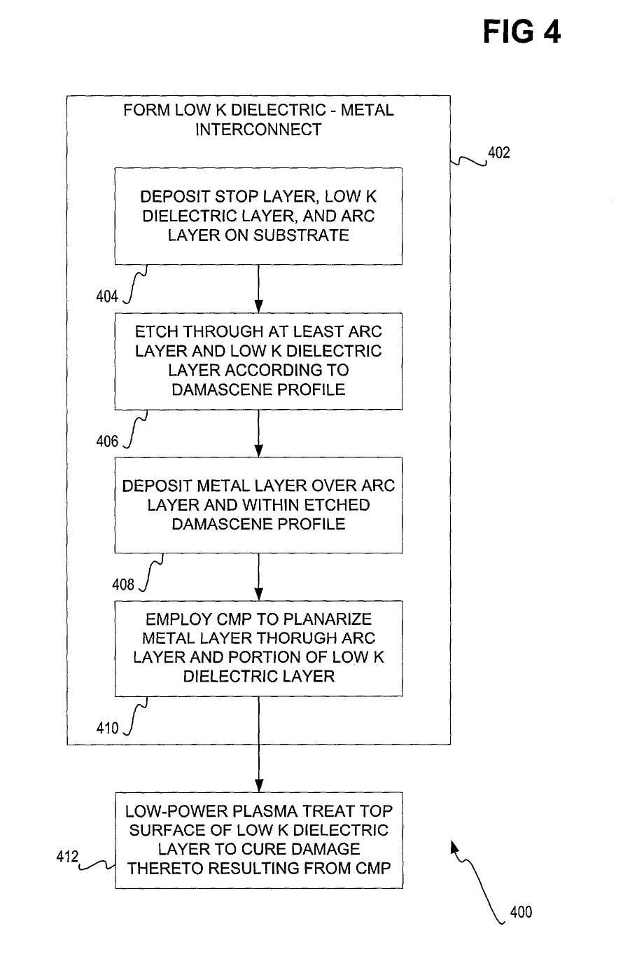

FIG. 4 shows a method according to an embodiment of the invention. First, a low k dielectric-metal interconnect is formed (402), such as the interconnect of the device 100 and the device 100′ as has been described. Formation of the low k dielectric-metal interconnect is specifically formed in one embodiment as follows. First, a stop layer, a low k dielectric layer, and an anti-reflective coating (ARC) layer are deposited on a substrate (404). The arc layer and the low k dielectric layer, and potentially also the stop layer, are etched through in accordance with a damascene profile (406). The damascene profile may be a single-damascene profile or a dual-damascene profile, such that the formation of 402 is a single-damascene process or a dual-damascene process, respectively.

Next, a metal layer is deposited over the ARC layer and within the etched damascene profile within the low k dielectric layer and potentially within the stop layer as well (408), depending on the particular damascene profile used. The metal is preferably copper, such that the interconnect is a low k dielectric-copper interconnect. CMP is employed to planarize this metal layer through the ARC layer and a portion of the low k dielectric layer (410). The CMP results in damage to the top surface of the low k dielectric layer, as has been indicated. For instance, metal ions, such as copper ions, and undesired CMP materials may be trapped within the top surface of the low k dielectric layer, causing undesired inter-line leakage current.

Therefore, the top surface is of the interconnect is treated with low-power plasma to cure the damage that resulted thereto from the CMP (412). As has been indicated, the plasma treatment may specifically be a helium plasma treatment. This removes or frees the undesired materials trapped in the top surface of the low k dielectric layer. As a result, undesired inter-line leakage currently is substantially reduced, if not totally eliminated.

It is noted that, although specific embodiments have been illustrated and described herein, it will be appreciated by those of ordinary skill in the art that any arrangement is calculated to achieve the same purpose may be substituted for the specific embodiments shown. This application is intended to cover any adaptations or variations of the present invention. Therefore, it is manifestly intended that this invention be limited only by the claims and equivalents thereof.

What is claimed is:

1. A method comprising:
forming a low k dielectric-metal interconnect having a top surface via a damascene process; and,
low-power plasma treating the top surface of the low k dielectric-metal interconnect to substantially cure any damage to the top surface resulting from the damascene process.

2. The method of claim 1, wherein forming the low k dielectric-metal interconnect comprises forming a low k dielectric-copper interconnect.

3. The method of claim 1, wherein forming the low k dielectric-metal interconnect via the damascene process comprises using a single-damascene process.

4. The method of claim 1, wherein forming the low k dielectric-metal interconnect via the damascene process comprises using a dual-damascene process.

5. The method of claim 1, wherein forming the low k dielectric-metal interconnect comprises employing chemical-mechanical planarization (CMP).

6. The method of claim 1, wherein forming the low k dielectric-metal interconnect results in damage to the top surface.

7. The method of claim 1, wherein forming the low k dielectric-metal interconnect results in at least one of undesired chemical-mechanical planarization (CMP) materials and metal ions to be trapped in the top surface.

8. The method of claim 1, wherein low-power plasma treating the top surface comprises helium plasma treating the top surface.

9. A method comprising:
depositing a stop layer, a low k dielectric layer, and an anti-reflective coating (ARC) layer on a substrate;
etching through at least two of the stop layer, the low k dielectric layer, and the ARC layer in accordance with a desired damascene profile;
depositing a metal layer over the stop layer and within the at least two of the stop layer, the low k dielectric layer, and the ARC layer as etched;
employing chemical-mechanical planarization (CMP) to planarize the metal layer through the stop layer and a portion of the low k dielectric layer; and,
low-power plasma treating a top surface of the low k dielectric layer as planarized to substantially cure any damage to the top surface resulting from the CMP.

10. The method of claim 9, wherein depositing the metal layer comprises depositing a copper layer.

11. The method of claim 9, wherein etching in accordance with the desired damascene profile comprises etching in accordance with a single-damascene profile.

12. The method of claim 9, wherein etching in accordance with the desired damascene profile comprises etching in accordance with a dual-damascene profile.

13. The method of claim 9, wherein employing the CMP results in damage to the top surface of the low k dielectric layer.

14. The method of claim 9, wherein employing the CMP results in at least one of undesired CMP materials and metal ions to be trapped in the top surface of the low k dielectric layer.

15. The method of claim 9, wherein low-power plasma treating the top surface comprises helium plasma treating the top surface.

16. A semiconductor device having a low k dielectric-metal interconnect comprising:
a stop layer;
a low k dielectric layer, the stop layer and the low k dielectric layer having a damascene profile; and,
a metal layer at least filling the damascene profile, chemical-mechanical planarization (CMP) employed to planarize the metal layer through a portion of the low k dielectric layer,
a top surface of the low k dielectric layer after planarization being low-power plasma treated to substantially cure any damage to the top surface resulting from the CMP.

17. The semiconductor device of claim 16, wherein the metal layer comprises a copper layer.

18. The semiconductor device of claim 16, wherein the damascene profile comprises one of a single-damascene profile and a dual-damascene profile.

19. The semiconductor device of claim 16, wherein the top surface has at least one of undesired CMP materials and metal ions trapped therein resulting from the CMP.

20. The semiconductor device of claim 16, wherein the low-power plasma comprises helium plasma.
